(19) United States
(12) Patent Application Publication
(10) Pub. No.: US 2025/0105064 A1
(43) Pub. Date: Mar. 27, 2025

(54) Electrical Performance Prediction Based On Structural Measurements Of Partially Fabricated Semiconductor Devices

(71) Applicant: KLA Corporation, Milpitas, CA (US)

(72) Inventor: Zhengquan Tan, Cupertino, CA (US)

(21) Appl. No.: 18/887,461

(22) Filed: Sep. 17, 2024

Related U.S. Application Data
(60) Provisional application No. 63/540,368, filed on Sep. 26, 2023.

(51) Int. Cl. H01L 21/66; G01N 21/21; G01N 21/95; H01L 29/775

(52) U.S. Cl. CPC H01L 22/14; G01N 21/211; G01N 21/9501; H10D 30/43

(57) ABSTRACT

Methods and systems for measurement of an expected electrical performance of a semiconductor device after device formation is complete based on structural measurements of the device in a partially fabricated state are described herein. In a further aspect, process parameters associated with a process step are adjusted based on the predicted electrical performance to improve process yield. In this manner, process parameters are tuned without having to wait several weeks for electrical performance test measurements to occur at the end of a process flow. In preferred embodiments, a Multiple Reflection Spectroscopic Ellipsometry (MRSE) system is employed to perform structural measurements of a semiconductor device in a partially fabricated state to predict electrical performance of the device at the end of the device fabrication process flow. MRSE based measurements are performed at one or more critical process steps where the structural measurements correlate strongly with final electrical performance.

### CROSS REFERENCE TO RELATED APPLICATION

The present application for patent claims priority under 35 U.S.C. §119 from U.S. provisional patent application Ser. No. 63/540,368 entitled “Electrical Parametric Metrology at Process Steps for Semiconductor Fabrication of Logic and DRAM Devices,” filed Sep. 26, 2023, the subject matter of which is incorporated herein by reference in its entirety.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput without the risk of sample destruction. A number of optical metrology based techniques including ellipsometry, scatterometry and reflectometry implementations and associated analysis algorithms are commonly used to characterize critical dimensions, film thicknesses, composition, overlay and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. For example, advanced memory and logic device structures, e.g., nanowire structures, forksheet structures, complementary field effect transistor (CFET) structures, multi-deck VNAND structures, etc., incorporate new complex three-dimensional geometry, dramatic topographic changes, and materials with diverse orientation and physical properties. These advanced devices are difficult to characterize. In addition, semiconductor devices are increasingly valued based on electrical performance after semiconductor device fabrication is complete. Important electrical performance metrics include drive current, threshold voltage, carrier mobility, current leakage, breakdown voltage, etc.

Traditionally, electrical performance testing, a.k.a., parametric test, is performed after device manufacturing is complete up to the metallization step, a.k.a., metal 1 step, or complete up to the packaging phase as part of a wafer acceptance step. At this point in the semiconductor fabrication process flow, all processing steps that impact electrical performance of the device under test are complete and cannot be altered. Therefore, devices that fail electrical performance testing at this point in the semiconductor process flow cannot be recovered.

Currently, physical metrology is employed to measure structural features, e.g., critical dimensions, shape, thickness, composition and other physical properties to target the physical shape of the device at the measured process step. These measurement results are often not connected to the final electrical performance of the device, which is often separated from the measurement data by hundreds of process steps and weeks of elapsed time. This limits the value offered by many existing tools, since the measurements are not directly correlated with final device performance. In addition, many existing process control and yield management tools do not offer insight into the sensitivity of various measured parameters to final device performance.

In some examples, measurements of the material composition of high-k dielectric layers have been used as indicators for process monitoring. For high-k materials such as SiHfON, it was found that differing percentages of nitrogen and hafnium, different deposition temperatures and deposition cycle times, different intermediate layers, etc., produce different dispersion values and different energy band structures. This affects chip performance at the end of the manufacturing process. An X-ray spectrometer has been utilized to accurately measure the material composition of high-k dielectric layers. However, X-ray spectroscopy suffers from high cost and low throughput, making it undesireable for use as a high throughput production monitoring tool.

In some other examples, dispersion properties of the high-k dielectric layer (e.g., refractive index, n, and extinction coefficient, k) have been used to calculate material composition based on empirical models. This approach has the advantage of lower cost and higher throughput relative to X-ray spectroscopic techniques. One such example is presented in U.S. patent application Ser. No. 13/524,053 assigned to KLA-Tencor Technologies, Corp.

Although the material composition of a high-k material layer is a strong indicator of deposition process parameters, it does not directly correlate with end of line electrical properties, such as leakage current, etc. For example, in the case of SiHfON, a shift of deposition rate and temperature may produce a film with differing structural defects or different band structure while material composition remains unchanged. The resulting structural defects or band structure may adversely increase leakage current, despite the fact that the material composition has not changed. Similarly, a process that produces a different material composition may also result in reduced structural defects and a more favorable band structure. In this case, monitoring based on material composition alone may result in a false negative result where fault is found based on material composition when in fact the material structure and properties results in reduced leakage current.

Attempts have been made to correlate physical measurements, e.g., CD, shape, thickness, etc., performed at a process step with electrical performance of the device after the process flow is complete. However, no system has emerged that is capable of in-line electrical performance metrology at one or more process steps to control the electrical performance of a device during a manufacturing process flow. In many examples, the measurement data is incomplete, the measurement system lacks sufficient sensitivity, or both.

X-ray based methods such as X-ray Photoemission Spectroscopy (XPS) and X-ray Fluorescence (XRF) perform atomic counts in thin films to determine thickness or composition. These measurements are slow, e.g., each measurement point requires multiple seconds, compared with optically based measurement techniques. Thus, many of the X-ray techniques are not applicable to high-volume measurement applications in a semiconductor manufacturing facility. Furthermore, some X-ray based measurement methods suffer from poor contrast, particularly in measurement applications where two or more layers include the same element, e.g., stacked layers of Titanium Nitride (TiN) and Titanium (Ti) of a Gate-All-Around (GAA) device, stacked layers of Zirconium oxide and aluminum oxide of a DRAM capacitor device, etc.

In general, a high throughput measurement system should be able to perform the desired measurement at a particular measurement site within one second, while maintaining measurement errors within desired limits, e.g., measurement uncertainty, accuracy, precision, and tool to tool matching. Existing high throughput optical metrology tools manufactured by KLA Corporation include the SpectraShape™ SS10k, SS11K, and SS12k tools focused on critical dimension and shape metrology, and SpectraFilm™ F1 and F10 tools focused on film metrology. Spectroscopic ellipsometry based measurement tools, such as the SpectraFilm™ F1 and SpectraFilm™ F10 tools, are employed to measure thickness and composition, e.g., thickness of high-K dielectric films and metal gate structures, dipole-doping layer composition, etc. Unfortunately, measurement sensitivity to ultra-thin layers is limiting many measurement applications.

In an attempt to overcome measurement sensitivity limitations, measurement times are lengthened to increase signal to noise ratio by averaging. However, the negative impact on measurement throughput is undesirable. In some other examples, multiple metrology targets are fabricated on a wafer and measured as part of a multi-target measurement in an attempt to break correlations among parameters of interest. However, this approach increases the complexity of the structures fabricated on the wafer, uses valuable wafer area for metrology specific targets, and in many fabrication process steps, multiple, different targets are not available because the distinguishing features have yet to be fabricated.

Ongoing reductions in feature size, increasing depths and layers of structural features, and increasing use of opaque material layers impose difficult requirements on optical metrology systems. Optical metrology systems must meet high precision and accuracy requirements for increasingly complex targets at high throughput to remain cost effective.

Along with the adoption of new dielectric materials and advanced structures, the need has arisen for measurement tools to predict the electrical performance properties of a finished semiconductor device based on measurements performed early in the manufacturing process. In some examples, high throughput monitoring tools are desired to monitor and control the geometry and bandgap of high-k layers, the geometry of electrical dipole layers, and channel stress to ensure a high yield of finished wafers that meet electrical performance targets. Early detection of deposition problems, etch problems, patterning problems, etc., is important because the complete manufacturing process of a semiconductor wafer is lengthy and expensive. For example, deposition of high-k materials often occurs at the beginning of a manufacturing process that takes over one month to complete.

In general, semiconductor device shapes and profiles are changing dramatically along with new process capabilities. In particular, advanced logic and memory devices must meet increasingly demanding specifications for Critical Dimension (CD) profiles. Thus, detailed features of geometric profiles must be measured accurately. Furthermore, it is desired that measurements of detailed features of geometric profiles at one or more process steps be employed to accurately predict electrical performance properties of a finished semiconductor device.

### SUMMARY

Methods and systems for measurement of an expected electrical performance of a semiconductor device after device formation is complete based on structural measurements of the device in a partially fabricated state are described herein. In a further aspect, process parameters associated with a measured process step, prior process steps, subsequent process steps, or any combination thereof are adjusted based on the predicted electrical performance to improve process yield. In this manner, process parameters are tuned without having to wait several weeks for electrical performance test measurements to occur at the end of a process flow.

During the process development cycle of device fabrication, the availability of accurate predictions of expected end of line electrical performance based on measurements performed during the fabrication process flow reduces the number of process cycles and the elapsed time associated with each process cycle to achieve a high yield process recipe. Moreover, during production, the availability of accurate measurements of expected end of line electrical performance during the fabrication process flow enables rapid process adjustments to compensate for process drift and increases yield.

Measurement data is collected from a semiconductor device at one or more process steps of a front end of line (FEOL) process flow. An electrical performance prediction engine estimates the expected electrical performance of the measured device at the conclusion of the FEOL process flow based on the measurement data collected well before the FEOL process flow is complete.

In general, electrical performance at the end of the FEOL process flow is a function of all of the physical process steps employed to form the device structures. However, many important electrical performance metrics are strong functions of a small number of critical process steps, and weak functions of the other process steps. Moreover, the values of many electrical performance metrics are not significantly changed by intervening process steps between a last critical process step and the final FEOL process step. Thus, in general, it is advantageous to select one or more critical process steps for measurement, including the last critical process step, to capture the process steps that strongly correlate with expected electrical performance. Conversely, it is not advantageous to select process steps subsequent to the last critical process step for measurement, as they do not strongly correlate with expected electrical performance.

In preferred embodiments, a Multiple Reflection Spectroscopic Ellipsometry (MRSE) system is employed to perform structural measurements of a semiconductor device in a partially fabricated state to predict electrical performance of the device at the end of the device fabrication process flow. MRSE based measurements are performed at one or more critical process steps where the structural measurements correlate strongly with final electrical performance. The values of expected electrical performance metrics, e.g., drive current, threshold voltage, carrier mobility, current leakage, breakdown voltage, etc., are determined based on the MRSE measurements at each of the one or more critical process steps.

In preferred embodiments, MRSE provides measurement sensitivity to critical structural features at critical process steps that enables accurate electrical performance predictions for advanced logic gate-all-around devices and DRAM devices. MRSE measurement recipes are developed with high sensitivity to material composition and feature size, e.g., CD, shape, film thickness, that strongly correlate with final device electrical performance.

In a further aspect, an optical modulation element is disposed in the optical path of the MRSE measurement system. In preferred embodiments, the optical modulation element is an optical element separate from the wafer and is not a portion of the semiconductor wafer. The physical interaction between the optical modulation element and the measurement beam changes the wavefront phase and amplitude properties of the measurement beam. The addition of an optical modulation element in the measurement beam path further enhances measurement sensitivity to critical parameters, e.g., CDs, shapes, and film thicknesses, and helps to break correlations between critical parameters that lead to undesirable measurement errors, excessive computational effort, or both.

In another further aspect, a metrology system implements an electrical performance prediction engine employed to predict values of one or more electrical performance metrics based on structural measurements as described herein. In one embodiment, an electrical performance prediction engine includes a structural measurement module and an electrical performance estimation module. A structural measurement module includes measurement models employed to estimate values of one or more parameters of interest characterizing the structure under measurement at each measurement site and each process step based on collected measurement signals. An electrical performance estimation module includes a process model employed to predict the values of one or more electrical performance metrics associated with each measurement site based on the corresponding estimated values of the structural parameters of interest. In another embodiment, an electrical performance prediction engine includes an electrical performance estimation module employed to directly predict the values of one or more electrical performance metrics associated with each measurement site based on the collected measurement signals.

In another further aspect, a metrology system implements a process update engine employed to determine an updated value of one or more process parameters characterizing one of the process steps before the last step of the set of FEOL process steps. In some examples, an updated value is associated with a process step performed before the measurements are performed. In these examples, the updated values of the one or more process parameters will change the process applied to subsequent wafers to be processed in the process flow. In some examples, the updated value is associated with a process step to be performed after the measurements are performed. In these examples, the updated values of the one or more process steps will change the process to be applied to the measured wafer and subsequent wafers in the process flow.

In another further aspect, expected electrical performance may be calculated based on measurements performed by a multiple pass spectroscopic measurement system and another metrology system.

In another further aspect, multiple pass measurements using different combinations of optical modulation targets are combined in a multi-target measurement to further enhance measurement sensitivity and break correlations.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified diagram illustrative of a timeline 210 representative of a typical semiconductor fabrication process flow.

FIG. 2 is a diagram illustrative of an electrical performance prediction engine and process update engine in one embodiment.

FIG. 3 is a diagram illustrative of an electrical performance prediction engine and a process update engine in another embodiment.

FIG. 4 depicts an embodiment of a metrology system for estimating electrical performance based on broadband spectroscopic measurements of semiconductor structures with multiple optical passes as described herein.

FIG. 5 depicts an embodiment 180 of a combined illumination source.

FIG. 6 depicts another embodiment of a metrology system for estimating electrical performance based on broadband spectroscopic measurements of semiconductor structures with multiple optical passes as described herein.

FIG. 7 is a simplified diagram illustrative of a nanosheet based semiconductor structure 150 in one embodiment.

FIG. 8 is a simplified diagram illustrative of two instances of a nanosheet based semiconductor structure as encountered by a multiple pass measurement beam in one example.

FIG. 9 is a simplified diagram illustrative of two instances of a nanosheet based semiconductor structure separated by a layer of silicon dioxide having a thickness of 50 nanometers as encountered by a multiple pass measurement beam.

FIG. 10 is a simplified diagram illustrative of two instances of a nanosheet based semiconductor structure separated by a layer of silicon dioxide having a thickness of 100 nanometers as encountered by a multiple pass measurement beam.

FIG. 11A is a simplified diagram illustrative of a thin film structure under measurement.

FIG. 11B is a simplified diagram illustrative of an optical modulation target employed as part of a multiple pass measurement, along with the primary depicted in FIG. 11A.

FIG. 12 illustrates a method 300 for measuring an expected electrical performance of a semiconductor device based on structural measurements of the device in a partially fabricated state as described herein.

### DETAILED DESCRIPTION

Reference will now be made in detail to background examples and some embodiments of the invention, examples of which are illustrated in the accompanying drawings.

Methods and systems for measurement of an expected electrical performance of a semiconductor device based on structural measurements of the device in a partially fabricated state are described herein. More specifically, multiple pass optical measurements of a partially fabricated structure with high sensitivity to structural properties enable accurate electrical performance prediction. Moreover, process parameters associated with the measured process step, prior process steps, subsequent process steps, or any combination thereof are adjusted based on the predicted electrical performance to improve process yield.

In this manner, process parameters are tuned without having to wait several weeks for electrical performance test measurements to occur at the end of the process flow. During the process development cycle of device fabrication, the availability of accurate predictions of expected end of line electrical performance based on measurements performed during the fabrication process flow reduces the number of process cycles and the elapsed time associated with each process cycle to achieve a high yield process recipe. Moreover, during production, the availability of accurate measurements of expected end of line electrical performance during the fabrication process flow enables rapid process adjustments to compensate for process drift and increases yield.

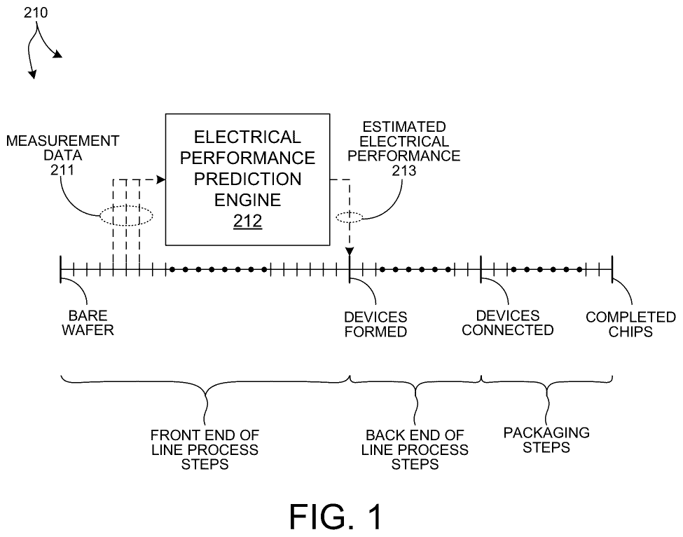

FIG. 1 is a simplified diagram illustrative of a timeline 210 representative of a typical semiconductor fabrication process flow. As depicted in FIG. 1, the typical semiconductor fabrication process flow starts with bare wafers and progresses through a set of front end of line (FEOL) process steps that result in a set of fully formed semiconductor devices fabricated on a wafer. After formation of the semiconductor devices, a set of back end of line (BEOL) steps are performed on the wafer to form the electrical interconnects among the fully formed devices. After electrical interconnect is complete, a set of packaging steps are performed to separate the devices from one another, seal, and package the discrete devices to form completed semiconductor integrated circuits, a.k.a., chips, ready for delivery to customers.

Traditionally, electrical performance testing is performed after the FEOL steps are completed. In some examples, electrical performance testing is performed before metallization steps of the set of BEOL process steps begin. In some examples, electrical performance testing is performed after the BEOL steps are complete, but before executing the packaging steps.

In the examples described herein, measurement data 211 is collected at one or more process steps of the set of FEOL process steps. Electrical performance prediction engine 212 estimates the expected electrical performance of the measured devices at the conclusion of the set of FEOL steps, based on measurement data collected well before the set of FEOL steps are actually completed.

By way of non-limiting example, important electrical performance metrics include drive current, threshold voltage, carrier mobility, current leakage, breakdown voltage, etc., for logic devices. In addition, capacitance, read and write speed, and reliability are important electrical performance metrics for memory structures, such as Dynamic Random Access Memory (DRAM). In general, the estimation of any suitable electrical performance metric based on measurements at prior process steps may be contemplated within the scope of this patent document.

In general, electrical performance at the end of the set of FEOL process steps is a function of all of the physical process steps employed to form the device structures. However, many important electrical performance metrics are strong functions of a small number of critical process steps, and weak functions of the other process steps. Moreover, the values of many electrical performance metrics are not significantly changed by intervening process steps between a last critical process step and the final FEOL process step. Thus, in general, it is advantageous to select one or more critical process steps for measurement, including the last critical process step, to capture the process steps that strongly correlate with expected electrical performance. Conversely, it is not advantageous to select process steps subsequent to the last critical process step for measurement, as they do not strongly correlate with expected electrical performance.

In some examples, a set of successive deposition and etch process steps are employed to form the gate structure of FINFET devices and Gate-All-Around (GAA) devices. At different measurement locations on a wafer, different devices are formed including different thicknesses of interface layers, high-K dielectric layers, metal gate layers, and optionally, dipole layers, that comprise the gate structure. The thicknesses of these layers are strongly correlated with the resulting threshold voltage of each corresponding device on the wafer after the device structure is fully formed. In these examples, measurements are performed at one or more of the gate formation process steps to accurately predict the expected threshold voltage associated with each measured device. In some of these examples, a dipole layer thickness of a few Angstroms is employed to meet precise specifications on device threshold voltage. Thus, measurement of the dipole layer thickness is critical to accurately predict threshold voltage.

In some embodiments, a multiple pass spectroscopic ellipsometry (MPSE) is employed to accurately measure the thickness of dipole layers of a few Angstroms. Moreover, the resulting measurements are employed to adjust one or more process parameters, e.g., deposition time, to adjust dipole layer thickness, and thus threshold voltage for subsequent wafers.

In some examples, a set of process steps are employed to form source, drain, and gate structures of FINFET devices and Gate-All-Around (GAA) devices. The geometry of these structures is strongly correlated with drive current and carrier mobility of each corresponding device on the wafer after the device structure is fully formed. In these examples, measurements are performed at one or more of the source, drain, and gate formation process steps to accurately predict the expected drive current and carrier mobility associated with each measured device. In some examples, measurements of channel shape, e.g., silicon based channel structures, are employed to estimate expected drive current. In some examples, measurements of induced channel stress are employed to estimate expected drive current. In some these examples, the geometry of Silicon Germanium deposited on Silicon channel structures is measured to infer channel stress, which, in turn, is employed to estimate expected drive current.

In general, several process steps in the fabrication of a GAA logic structure are strongly correlated with electrical performance of the fully formed device. In one example, the thicknesses of alternating Silicon/Silicon Germanium layers formed during the set of Silicon/Silicon Germanium epitaxial process steps correlate with drive current and carrier mobility. In another example, the critical dimensions of fin structures formed during the set of fin etch process steps correlate with drive current and carrier mobility. In another example, the shallow trench isolation (STI) recess formed during the set of STI formation process steps correlate with drive current and carrier mobility. In another example, the critical dimensions of fin structures formed during the set of gate etch process steps correlated with drive current and carrier mobility. In another example, the spacer thickness formed during a gate spacer etch process step is correlated with drive current and carrier mobility. In another example, the spacer etch-back and Silicon Germanium recess formed during the set of Silicon Germanium recess process steps is correlated with drive current and carrier mobility. In another example, the inner spacer critical dimensions formed during the set of inner spacer etch/clean process steps correlated with drive current and carrier mobility. In another example, the critical dimensions and heights of the Silicon Germanium stressors formed during the Silicon Germanium epitaxial steps are correlated with drive current and carrier mobility. In another example, the critical dimensions of nanowire structures formed at the nanowire release step are correlated with threshold voltage. In another example, the gate oxide thickness formed over the nanowire structure at the gate over nanowire epitaxial step is correlated with threshold voltage.

In preferred embodiments, a Multiple Reflection Spectroscopic Ellipsometry (MRSE) system is employed to perform structural measurements of a semiconductor device in a partially fabricated state to predict electrical performance of the device at the end of the device fabrication process flow. MRSE based measurements are performed at one or more critical process steps where the structural measurements correlate strongly with final electrical performance. The values of expected electrical performance metrics, e.g., drive current, threshold voltage, carrier mobility, current leakage, breakdown voltage, etc., are determined based on the MRSE measurements at each of the one or more critical process steps.

In preferred embodiments, MRSE provides measurement sensitivity to critical structural features at critical process steps that enables accurate electrical performance predictions for advanced logic gate-all-around devices and DRAM devices. MRSE measurement recipes are developed with high sensitivity to material composition and feature size, e.g., CD, shape, film thickness, that strongly correlate with final device electrical performance.

Conventional optical measurements of semiconductor structures are performed with one optical pass of the structure under measurement, i.e., the measurement beam interrogates the structure under measurement only once in its path from the illumination source to the detector.

In one aspect, the optical subsystem of a semiconductor measurement system is configured such that the measurement beam is incident on the surface of the semiconductor wafer more than once in an optical path between the illumination source and the detector. In some embodiments, the measurement beam is incident multiple times at the same measurement site on the semiconductor wafer in an optical path between the illumination source and the detector. In some other embodiments, the measurement beam is incident at different measurement sites on the semiconductor wafer in an optical path between the illumination source and the detector. In these embodiments, an instance of the same nominal structure under measurement is fabricated at each different measurement site.

Multiple pass optical measurements of semiconductor structures amplify measurement sensitivity. To first approximation, each optical ray defined as a unique wavelength and angle of incidence is incident on the same nominal structure of interest multiple times. At each pass, new signal information adds coherently with the prior signal information encoded in the optical ray. Thus, the amplification of the measurement signal is proportional to the square of the number of passes. For example, a multiple pass optical measurement that interrogates the same instance of a structure under measurement three times, or three different instances of the same nominal structure under measurement, may increase measurement sensitivity by a factor of nine.

In general, amplified measurement signal sensitivity induced by multiple pass measurements enables greater measurement accuracy, precision, and stability, reduced measurement error, and faster measurement. In addition, amplified measurement signal sensitivity induced by multiple pass measurements enables accurate estimation of electrical performance after FEOL process steps are completed based on measurements performed before the FEOL process steps are completed.

In some embodiments, multiple pass measurements are employed in semiconductor process development and production metrology of shape features, film thicknesses, material composition, material bandgap measurements, channel stress, or other structural features in real time. This, in turn, enables accurate estimation of expected electrical performance before completion of the FEOL process steps. For example, multiple pass measurements may be employed to monitor dipole doping layers having a very small number of mono-atomic-layers.

Multiple pass measurements of a wide range of structures are contemplated within the scope of this patent document, including, but not limited to: FinFET devices, Gate-all-around (GAA) nanosheet and nanowire devices, including structures at all transistor formation processes, including nanosheet formation, SiGe recess, Inner spacer formation, and epitaxial growth steps, logic/foundry devices fabricated in accordance with High-K and Metal Gate (HKMG) processes, DRAM devices including High-K multi-layer stacks, e.g., Zirconium oxide and aluminum oxide multilayers, and any other future devices that have nanometer-scale feature sizes.

In some examples, multiple pass measurements enable accurate measurement of structural features of individual transistor structures comprising GAA logic devices, including GAA logic devices having three or more transistors vertically stacked at one wafer location.

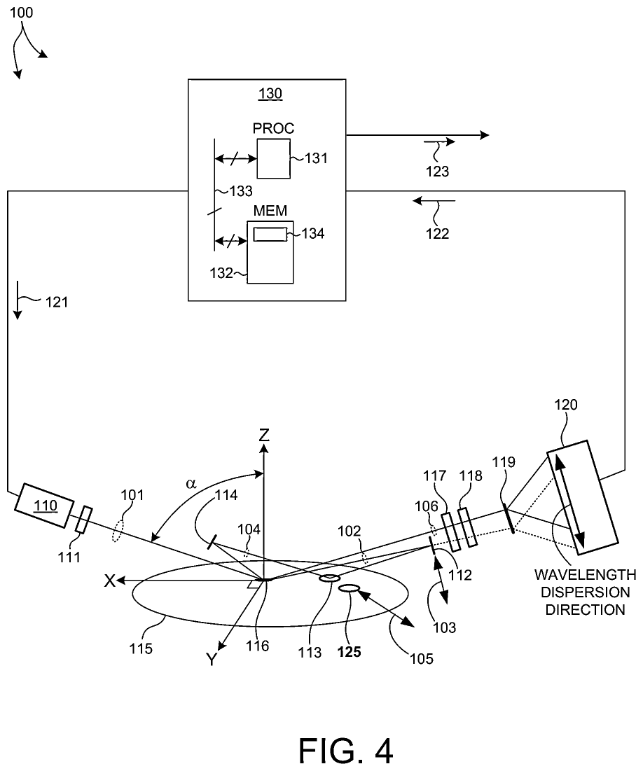

FIG. 4 depicts an exemplary, multiple pass metrology system 100 for performing broadband spectroscopic measurements of semiconductor structures (e.g., film thickness, critical dimensions, overlay, etc.). As depicted in FIG. 4, metrology system 100 is configured as an oblique incidence, broadband spectroscopic ellipsometer. However, in general, multiple pass metrology system 100 may also include additional spectroscopic ellipsometers, a spectroscopic reflectometer, scatterometer, or any combination thereof.

Metrology system 100 includes an illumination source 110 that generates a beam of illumination light 101 incident on a wafer 115. Illumination source 110 includes one or more illumination sources that emit illumination light including wavelengths in a range from 140 nanometers to 2,500 nanometers. In some examples, a single illumination source emits illumination light having wavelengths spanning a range from 170 nanometers to 900 nanometers. In some other examples, a laser sustained plasma light source emits illumination light having wavelengths spanning a range from 150 nanometers to 900 nanometers.

In some embodiments, illumination source 110 is a combined illumination source that emits illumination light in the ultraviolet, visible, and infrared spectra, including ultraviolet wavelengths down to 140 nanometers and infrared wavelengths greater than two micrometers, e.g., illumination wavelengths ranging from 140 nanometers to 2,500 nanometers. In some other embodiments, illumination source 110 is a combined illumination source that emits illumination light including wavelengths in a range from 140 nanometers to 7,000 nanometers.

In some embodiments, combined illumination source 110 includes a supercontinuum laser source and a laser sustained plasma light source. The supercontinuum laser source provides illumination at wavelengths greater than two micrometers, and in some embodiments, up to 5 micrometers, or more. The laser sustained plasma (LSP) light source (a.k.a., laser driven plasma source) produces photons spanning a wavelength range from 120 nanometers to 2500 nanometers, and beyond. The pump laser of the LSP light source may be continuous wave or pulsed. In some embodiments, combined illumination source 110 includes a supercontinuum laser source and an arc lamp, such as a Xenon arc lamp. However, a laser-driven plasma source produces significantly more photons than a Xenon lamp across the entire wavelength range from 120 nanometers to 2500 nanometers, and is therefore preferred.

In general, combined illumination source 110 includes a combination of a plurality of broadband or discrete wavelength light sources. The light generated by combined illumination source 110 includes a continuous spectrum or parts of a continuous spectrum, from ultraviolet to infrared (e.g., vacuum ultraviolet to long infrared). In general, combined illumination light source 110 may include a supercontinuum laser source, an infrared helium-neon laser source, a silicon carbide globar light source, a tungsten halogen light source, one or more infrared LEDs, one or more infrared lasers or any other suitable infrared light source generating wavelengths greater than two micrometers, and an arc lamp (e.g., a Xenon arc lamp), a deuterium lamp, a LSP light source, or any other suitable light source generating wavelengths less than two micrometers including visible and ultraviolet wavelengths.

In general, combined illumination source 110 includes multiple illumination sources optically coupled in any suitable manner. In some embodiments, light emitted by a supercontinuum laser source is directly coupled through the plasma generated by the ultraviolet/visible light source.

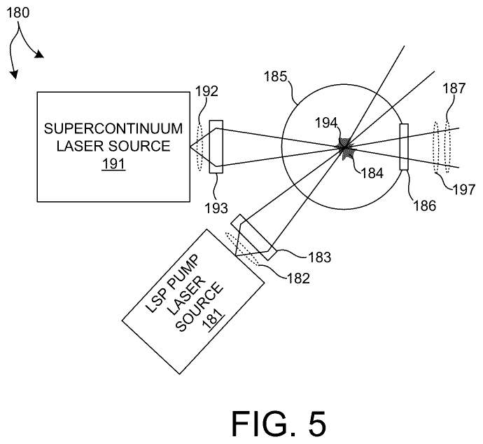

FIG. 5 depicts an embodiment 180 of a combined illumination source 110. As depicted in FIG. 5, a LSP pump laser source 181 generates pump light 182 that is focused by focusing optics 183 to sustain a plasma 184 contained by bulb 185. Plasma 184 generates broadband spectrum light over a wavelength range of ultra-violet to short infrared. Bulb 185 includes an exit port 186. LSP output light 187 is the portion of light from plasma 184 that passes through exit port 186 and is directed towards the illumination optics subsystem as described with reference to FIG. 4. In addition, supercontinuum laser source 191 generates infrared light 192 that is focused by focusing optics 193 to a focus 194 at or near plasma 184. Supercontinuum output light 197 is the portion of light from the focus 194 that passes through exit port 186 and is directed towards the illumination subsystem as described with reference to FIG. 4. In one example, the LSP output light 187 and supercontinuum output light 197 are co-located. In this manner, infrared light 197 from supercontinuum source 191 is effectively combined with ultraviolet/visible light 187 from LSP laser source 181. In one example, LSP output light 187 and supercontinuum output light 197 have the same or similar numerical aperture. In another example, LSP output light 187 and supercontinuum output light 197 have different numerical aperture. In some embodiments, the LSP pump laser source 181 is a continuous wave laser. In some other embodiments, the LSP pump laser source 181 is a pulsed laser.

As depicted in FIG. 4, metrology system 100 includes optical elements configured to direct a measurement beam incident on the surface of wafer 115 multiple times in an optical path between illumination source 110 and detector 120. In the embodiment depicted in FIG. 4, reflective elements 112 and 114 are positioned in the optical path to direct light from measurement site 116 back to measurement site 116 in a second pass.

As depicted in FIG. 4, metrology system 100 includes an illumination subsystem configured to direct illumination light 101 to one or more structures formed at measurement site 116 on wafer 115. The illumination subsystem may include any type and arrangement of optical filter(s), polarizing component, field stop, pupil stop, etc., known in the art of spectroscopic metrology. As depicted in FIG. 1, the illumination subsystem includes light source 110 and polarizing component 111. As depicted in FIG. 4, the beam of illumination light 101 passes through polarizing component 111 as the beam propagates from the illumination source 110 to wafer 115. Beam 101 illuminates a portion of wafer 115 over a measurement site 116. In some embodiments, illumination light 101 is incident at wafer 115 at an angle of incidence, α, at or near 65 degrees from normal incidence.

In addition, the illumination subsystem may include filters, masks, beam shaping optics, illumination pupils, apodizers, etc. For example, the illumination subsystem may include an illumination field stop (not shown) and one or more optical filters (not shown). The illumination field stop controls the field of view (FOV) of the illumination subsystem and may include any suitable commercially available field stop. The optical filters are employed to control light level, spectral output, or both, from the illumination subsystem. In some examples, one or more multi-zone filters are employed as optical filters.

In some examples, noise and polarization optimization are performed to improve the performance of illumination source 110. In some examples, depolarization is achieved by use of multimode fibers, a Hanle depolarizer, or an integration sphere. In some examples, the illumination source etendue is optimized by use of light guides, fibers, and other optical elements (e.g., lenses, curved mirrors, apodizers, etc.). In some examples, source coherence or coherence effects are mitigated by coherence breaking techniques, or are otherwise accounted for by modeling and simulation.

Polarizing component 111 generates the desired polarization state exiting the illumination subsystem. In some embodiments, the polarizing component includes a polarizer, a compensator, or both, and may include any suitable commercially available polarizing component. The polarizer, compensator, or both, can be fixed, rotatable to different fixed positions, or continuously rotatable. Although the illumination subsystem depicted in FIG. 4 includes one polarizing component, the illumination subsystem may include more than one polarizing component. In some embodiments, a polarizer of polarizing component 111 is a Magnesium Fluoride Rochon polarizer. In some embodiments, a compensator of polarizing component 111 includes a quartz waveplate, a Magnesium Fluoride waveplate, a Calcium Fluoride K-prism, a Calcium Fluoride double Fresnel rhomb, or any combination thereof. In some embodiments, a compensator of polarizing component 111 includes one or more waveplates. In some of these embodiments, a first waveplate includes a desired retardation over a first wavelength range and a second waveplate includes a desired retardation over the first wavelength range, and in some embodiments, a second, different wavelength range, etc.

As depicted in FIG. 4, illumination beam 101 is incident on wafer 115 at measurement site 116. Illumination beam 101 physically interacts with one or more structures under measurement at measurement site 116. The reflected beam 102 includes changes in wavefront phase and amplitude characteristics induced by the physical interaction.

As depicted in FIG. 4, beam 102 is reflected by reflective element 112 and is incident at site 113. In some embodiments site 113 is a portion of wafer 115 that includes another instance of the one or more structures under measurement at measurement site 116. In these embodiments, beam 102 physically interacts with the second instance of the one or more structures under measurement at site 113. The reflected beam 104 includes changes in wavefront phase and amplitude characteristics induced by the physical interaction.

As depicted in FIG. 4, beam 104 is reflected by reflective element 114 and is incident at measurement site 116 in a second pass. Beam 104 physically interacts with the instance of the one or more structures under measurement at measurement site 116. The reflected beam 106 includes changes in wavefront phase and amplitude characteristics induced by the physical interaction.

Metrology system 100 also includes a collection optics subsystem configured to collect light generated by the interaction between the one or more structures and the measurement beam and focus the collected light at or near a dispersive element, e.g., a spectrometer slit, of a spectrometer. The collection optics subsystem may include any type and arrangement of optical filter(s), polarizing component, field stop, pupil stop, etc., known in the art of spectroscopic metrology.

As depicted in FIG. 4, beam 106 passes through compensator 117 and analyzer 118 as beam 106 propagates from wafer 115 to dispersive element 119 of the spectrometer. As depicted in FIG. 4, the collection optics subsystem includes a polarizing component that analyzes the polarization state of the collected light. In some embodiments, the polarizing component includes an analyzer, a compensator, or both, and may include any suitable commercially available polarizing component. The analyzer, compensator, or both, can be fixed, rotatable to different fixed positions, or continuously rotatable. The collection subsystem depicted in FIG. 4 includes a compensator 117 and an analyzer 118. In general, a collection optics subsystem may include any number of polarizing elements.

In some embodiments, compensator 117 includes a quartz waveplate, a Magnesium Fluoride waveplate, a Calcium Fluoride K-prism, a Calcium Fluoride double Fresnel rhomb, or any combination thereof. In some embodiments, compensator 117 includes one or more waveplates. In some of these embodiments, a first waveplate includes a desired retardation over a first wavelength range and a second waveplate includes a desired retardation over the first wavelength range or a second, different wavelength range, etc. In some embodiments, analyzer 118 is a Magnesium Fluoride Rochon analyzer.

In the embodiment depicted in FIG. 4, a spectrometer subsystem includes dispersive element 119, and one or more optics having reflective focusing power (not shown). Dispersive element 119 is typically located at or near a pupil plane of the collection optics subsystem. Dispersive element 119 disperses the light into discrete wavelengths on the active surface of detector 120.

Dispersive element 119 is typically a diffraction grating or a dispersive prism. In some embodiments, dispersive element 119 includes one or more segments and each segment receives light from one or more corresponding apertures of a collection mask. In this manner, light dispersed by dispersive element 119 includes light corresponding to one or more discrete angles of incidence at the wafer. In some embodiments, dispersive element 119 is a planar diffraction grating. In some of these embodiments, the planar diffraction grating is segmented to split the pupil into segments each corresponding to a different set of discrete angles of incidence at the wafer. Further details regarding pupil splitting are described in U.S. Pat. No. 10,690,602 to KLA-Tencor Corporation, the content of which is incorporated herein by reference in its entirety.

As depicted in FIG. 4, detector 120 receives light collected from wafer 115 at one or more angles of incidence, multiple wavelengths, e.g., 140 nanometers to 2,500 nanometers, and one or more polarization states. In the embodiment depicted in FIG. 4, the collection optics subsystem directs light to detector 120 and the detector 120 generates output signals 122 responsive to light collected from the one or more structures under measurement. The dispersive element 119 linearly disperses diffracted light according to wavelength along one dimension of detector 120 (i.e., the wavelength dispersion direction noted in FIG. 4). Dispersive element 119 causes a spatial separation among different wavelengths of light projected onto the surface of detector 120. In this manner, light collected from measurement site 116 having a particular wavelength is projected onto detector 120 at a spatial location that is different from light collected from measurement site 116 having another, different wavelength.

In the aforementioned example, the measurement beam twice interacts with the first instance of the one or more structures under measurement at measurement site 116 in two passes, and once interacts with the second instance of the one or more structures under measurement in one pass. In this example, beam 106 includes wavefront phase and amplitude information associated with three interactions with the one or more structures under measurement.

In another embodiment, a reflective element coupled to metrology system 100 is located at site 113. In one embodiment, structural element 125 depicted in FIG. 4 is a reflective element separate from wafer 115, i.e., reflective element 125 is not a portion of wafer 115. Rather, reflective element 125 is directly or indirectly coupled to a frame that supports other optical elements of metrology system 100. In the embodiment depicted in FIG. 4, reflective element 125 is coupled to an actuator subsystem 105, e.g., a linear actuator. Actuator subsystem 105 is coupled to metrology system 100 and selectively moves reflective element 125 to site 113. In this embodiment, beam 102 is reflected by reflective element 112 and is incident on a reflective element present at site 113. In this embodiment, beam 102 simply reflects off the reflective element 125, and reflected beam 104 includes approximately the same wavefront phase and amplitude characteristics as beam 102.

In this example, the measurement beam twice interacts with the first instance of the one or more structures under measurement at measurement site 116 in two passes. In this example, beam 106 includes wavefront phase and amplitude information associated with two interactions with the one or more structures under measurement.

In the embodiment depicted in FIG. 4, reflective element 112 is coupled to an actuator subsystem 103, e.g., a linear actuator. Actuator subsystem 103 is coupled to metrology system 100 and selectively moves reflective element 112 in/out of the measurement beam path. In one configuration, actuator subsystem 103 moves reflective element 112 out of the measurement beam path. In this configuration, beam 102 passes through compensator 117 and analyzer 118 as beam 102 propagates from wafer 115 to dispersive element 119 of the spectrometer (depicted as a dashed line in FIG. 4).

In this example, the measurement beam interacts once with the first instance of the one or more structures under measurement at measurement site 116 in one pass. In this example, beam 102 includes wavefront phase and amplitude information associated with one interaction with the one or more structures under measurement as is the case in a conventional SE metrology subsystem. In some examples, single pass measurements may be convenient to perform for purposes of calibration, baseline validation, etc.

In the embodiment depicted in FIG. 4, metrology system 100 is easily configured to perform single pass, double pass, and triple pass measurements by simply controlling the position of reflective elements 112 and 125 in or out of the measurement beam path.

Although, metrology system 100 is optically configured in a two-pass configuration, in general, metrology system 100 may be optically configured in an N-pass configuration, where N is any positive, integer number greater than one. Although, metrology system 100 includes two reflective elements to direct light from measurement site 116 back to measurement site 116 in a second pass, in general, any suitable arrangement including any number of reflective optical elements to direct light from measurement site 116 back to measurement site 116 may be contemplated within the scope of this patent document.

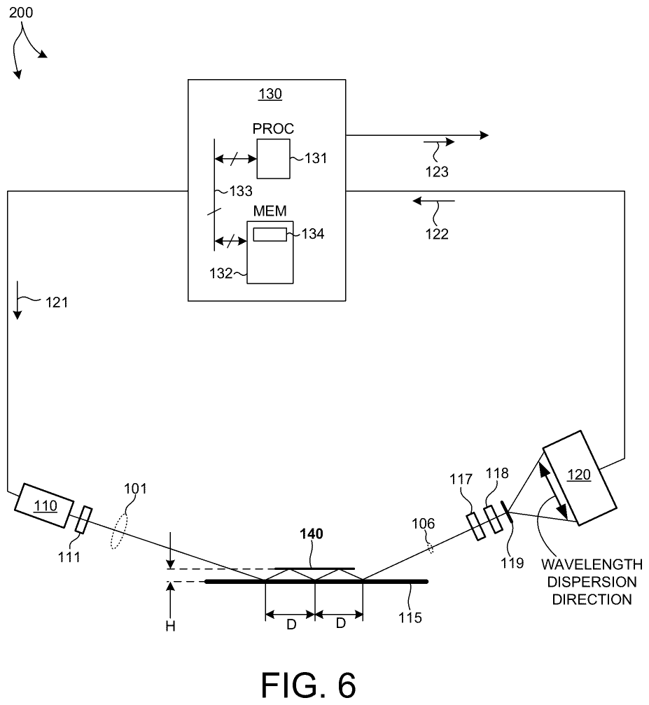

FIG. 6 depicts an exemplary, multiple pass metrology system 200 for performing broadband spectroscopic measurements of semiconductor structures (e.g., film thickness, critical dimensions, overlay, etc.). As depicted in FIG. 6, metrology system 200 is configured as an oblique incidence, broadband spectroscopic ellipsometer. However, in general, multiple pass metrology system 100 may also include additional spectroscopic ellipsometers, a spectroscopic reflectometer, scatterometer, or any combination thereof. Like numbered elements depicted in FIG. 6 are analogous to those described with reference to metrology system 100 described with reference to FIG. 4.

In the embodiment depicted in FIG. 6, a planar reflector 140 having a planar reflective surface is disposed over a portion of wafer 115 and facing the wafer surface. Planar reflector 140 is positioned in the optical path of the measurement beam and directs light from one measurement site to another measurement site on the surface of wafer 115. Each measurement site on wafer 115 includes a separate instance of one or more structures under measurement.

Planar reflector 140 is directly or indirectly coupled to a frame that supports other optical elements of metrology system 200. In some embodiments, planar reflector 140 is coupled to an actuator subsystem (not shown) that is coupled to metrology system 100. The actuator subsystem controls the position and orientation of planar reflector 140 relative to the surface of wafer 115 to ensure that the measurement beam is incident on more than one instance of one or more structures under measurement. For example, the planar reflector 140 should be positioned at a uniform height, H, above the surface of wafer 115 to ensure that the measurement beam is incident on wafer 115 at successive measurement sites separated by a distance, D. Distance, D, is known apriori as the distance between repeated instances of a structure under measurement, along with the angle of incidence of illumination beam 101. Based on the known angle of incidence, and distance, D, basic geometry is employed to calculate the desired separation distance, H.

In the embodiment depicted in FIG. 6, the measurement beam simply reflects off planar reflector 140 and with negligible change to the wavefront phase and amplitude characteristics as the measurement beam. However, at each incidence with wafer 115, the measurement beam interacts with an instance of the one or more structures under measurement. In this example, beam 106 includes wavefront phase and amplitude information associated with three interactions with the one or more structures under measurement.

In the embodiment depicted in FIG. 6, the measurement beam interacts with three instances of a structure under measurement. However, in general, planar reflective element 140 may be sized to accommodate two or more instances of a structure under measurement. In some embodiments, planar reflective element 140 is sized to accommodate up to ten instances of a structure under measurement.

In a further aspect, an optical modulation element is disposed in the optical path of the measurement system. In preferred embodiments, the optical modulation element is an optical element separate from the wafer and is not a portion of the semiconductor wafer. The physical interaction between the optical modulation element and the measurement beam changes the wavefront phase and amplitude properties of the measurement beam. The addition of an optical modulation element in the measurement beam path further enhances measurement sensitivity to critical parameters, e.g., CDs, shapes, and film thicknesses, and helps to break correlations between critical parameters that lead to undesirable measurement errors, excessive computational effort, or both. In some examples, measurement sensitivity may be amplified 6× to 25×, or more, by employing multiple pass measurements including optical modulation.

In preferred embodiments, one or more optical modulation targets are mounted to the measurement tool (not the wafer). Furthermore, the optical modulation targets are selectable for the measurement application at hand to amplify measurement sensitivity. The measurement signal response induced by each optical modulation target is calibrated periodically and the targets themselves are maintained in a controlled environment that minimizes drift over time. In general, any number of optical modulation targets may be loaded onto a measurement system. In some embodiments, a measurement tool includes a positioning system that selectively positions one or more optical modulation targets in the measurement beam path. In some embodiments, the positioning system moves an optical modulation targets from a storage position on board the measurement system to a position in the measurement path, and vice-versa. In some embodiments the positioning system, includes a carriage storing one or more optical modulation targets, and selectively moves each of the targets into the measurement path in accordance with a measurement recipe.

In some embodiments, optical modulation targets may be fabricated on a wafer under measurement. However, this approach is less desirable because the targets occupy valuable real estate on a wafer, cannot be as easily calibrated, are less likely to be mechanically and optically stable over time, cannot easily be adapted to new designs, etc. In addition, limiting the number of optical modulation targets to the number that can be accommodated within available area within the scribe lines of a wafer limits the process window that can be explored and potentially reduces the achievable yield.

In one embodiment, structural element 125 depicted in FIG. 4 is an optical modulation element separate from wafer 115, i.e., optical modulation element 125 is not a portion of wafer 115. In preferred embodiments, optical modulation element 125 is directly or indirectly coupled to a frame that supports other optical elements of metrology system 100. In the embodiment depicted in FIG. 4, optical modulation element 125 is coupled to an actuator subsystem 105, e.g., a modulator positioning subsystem. Actuator subsystem 105 is coupled to a structural element of metrology system 100 and selectively moves optical modulation element 125 in/out of the measurement beam path at site 113. In this embodiment, beam 102 is reflected by reflective element 112 and is incident on optical modulation element 125 present at site 113. In this embodiment, beam 102 physically interacts with one or more structures of optical modulation element 125 at site 113. The reflected beam 104 includes changes in wavefront phase and amplitude characteristics induced by the physical interaction.

In this example, the measurement beam twice interacts with the first instance of the one or more structures under measurement at measurement site 116 in two passes and interacts once with optical modulation element 125 in one pass. In this example, beam 106 includes wavefront phase and amplitude information associated with two interactions with the one or more structures under measurement and one interaction with optical modulation element 125.

In another embodiment, planar reflective element 140 depicted in FIG. 6 includes one or material layers that induce changes in wavefront phase and amplitude characteristics during physical interaction with the measurement beam. As such, in these embodiments, planar reflective element 140 is also an optical modulation element. In the embodiment depicted in FIG. 6, the measurement beam twice interacts with optical modulation element 140, in addition to three interactions with different instances of the primary target disposed on wafer 115. Thus, in this example, beam 106 includes wavefront phase and amplitude information associated with two interactions with optical modulation element 140 and three interactions with the primary target at three different measurement sites on wafer 115.

In the embodiment depicted in FIG. 4, the optical modulation element 125 is located at site 113 when inserted into the measurement beam path between the illumination source and the detector. In this configuration, the measurement beam interacts with the primary target at measurement site 116, the optical modulation target at site 113, and again with the primary target at measurement site 116. However, in general, any number of interactions with any number of instances of the primary target, any number of interactions with any number of the same or different optical modulation targets, and any order of interactions with primary and optical modulation targets, may be contemplated within the scope of this patent document.

In general, an optical modulation element is any structure that changes the wavefront phase and amplitude characteristics of the measurement beam. Exemplary optical modulation elements include, but are not limited to: a planar, bare crystalline silicon substrate, a layer of silicon dioxide deposited over a bare crystalline silicon substrate, a patterned structure fabricated on a layer of silicon dioxide deposited over a bare crystalline silicon substrate, a mirror, a filter, an optical amplifier, an optical bandgap filter, a waveguide, a diffraction grating, a dielectric Bragg reflector, etc.

In some embodiments, the optical modulator element is tunable, e.g., by changing the orientation or position of the optical modulator element with respect to the measurement beam, by applying a voltage to the optical modulator element, etc. For example, thin-film interference filters, tunable, Fabry-Perrot filters, MEMS-based Fabry-Perot filters, waveguides, diffraction gratings, dielectric Bragg reflectors (DBR) are positional optical components that enable modulation of measurement target sensitivity.

In some embodiments, the optical modulator includes a silicon based filter or mirror that passes light within a specific spectral range, e.g., UV to IR, designed to meet requirements for SCD or film measurements.

In general, an optical modulation element is designed to achieve a desired optical functionality and structural stability. For example, optical modulation elements fabricated with silicon, amorphous silicon, silicon dioxide, silicon nitride, etc., offer good optical performance and are mechanically and optically stable. Beyond material selection, the optical properties of an optical modulation element may be tuned by adjusting the thickness of layers of the filter stack, controlling the position and orientation of the optical modulation element with respect to the measurement beam, controlling a voltage applied to the optical modulation element, etc.

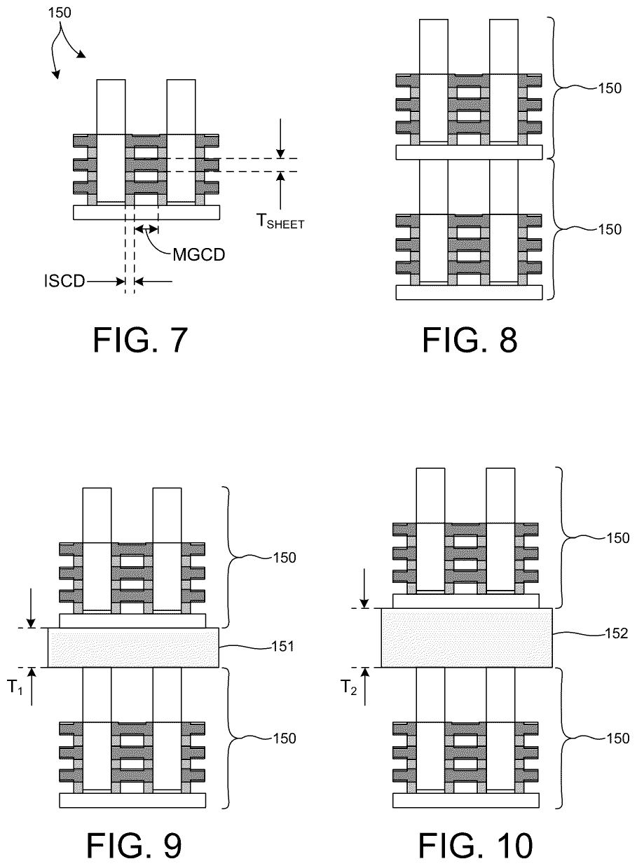

FIG. 7 is a simplified diagram illustrative of a nanosheet based semiconductor structure 150 in one embodiment. FIG. 7 depicts the nanosheet based semiconductor structure 150 after the Silicon Germanium (SiGe) release step. Several geometric parameters are critical after the SiGe release step. Exemplary critical parameters include the metal gate critical dimensions associated with each nanosheet, e.g., MGCD, the thickness associated with each nanosheet, e.g., T_{SHEET}, the shape profile of the inner spacers, e.g., ISCD, etc. Independent measurement of these dimensions and shape profiles is very challenging given the complexity of the structures and the relatively low volume of the critical dimensions and features.

In some embodiments, a two pass measurement is performed without an optical modulation element in the optical beam path as described with respect to FIGS. 4 and 6. FIG. 8 is a simplified diagram illustrative of two instances of nanosheet based semiconductor structure 150. FIG. 8 visually illustrates the stack up of two instances of nanosheet based semiconductor structure 150 as encountered by a multiple pass measurement beam directed to interrogate two instances of nanosheet based semiconductor structure 150.

In some embodiments, a two pass measurement is performed with an optical modulation element in the optical beam path as described with respect to FIGS. 4 and 6. FIG. 9 is a simplified diagram illustrative of two instances of nanosheet based semiconductor structure 150 separated by a layer of silicon dioxide 151 having a thickness of 50 nanometers. FIG. 9 visually illustrates the stack up of one instance of nanosheet based semiconductor structure 150, an instance of an optical modulation target, and another instance of nanosheet based semiconductor structure 150 as encountered by a multiple pass measurement beam directed to interrogate two instances of nanosheet based semiconductor structure 150 and an instance of an optical modulation target.

FIG. 10 is a simplified diagram illustrative of two instances of nanosheet based semiconductor structure 150 separated by a layer of silicon dioxide 151 having a thickness of 100 nanometers. FIG. 10 visually illustrates the stack up of one instance of nanosheet based semiconductor structure 150, an instance of an optical modulation target, and another instance of nanosheet based semiconductor structure 150 as encountered by a multiple pass measurement beam directed to interrogate two instances of nanosheet based semiconductor structure 150 and an instance of an optical modulation target.

In another aspect, an optical modulation target is combined with multiple pass measurements to amplify measurement sensitivity to thickness and composition. In some embodiments, the primary target includes at least one layer of a material with a specified thickness, and the optical modulation element also includes the at least one layer of the material with the specified thickness, or a different thickness. In some of these embodiments, the optical modulation element includes the at least one layer of the material with a specified thickness that is an integer multiple of the corresponding specified thickness of the material in the primary target.

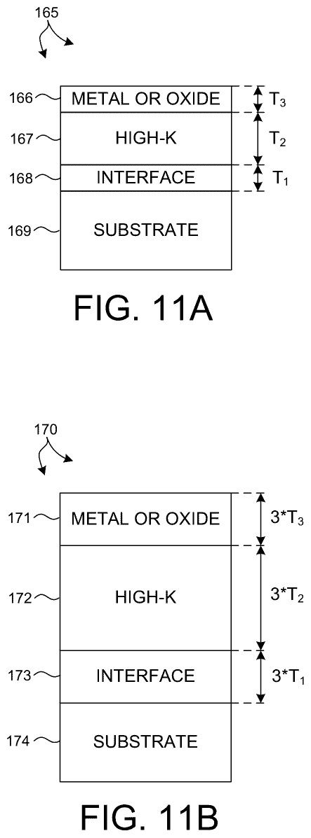

In some embodiments, a film thickness target includes multiple layers of different materials. For example, FIG. 11A is a simplified diagram illustrative of a thin film structure under measurement, i.e., a primary target. As depicted in FIG. 11A, the primary film thickness target 165 includes a substrate 169, e.g., Silicon, an interface layer 168, e.g., Silicon dioxide, having a thickness, T₁, a high-K dielectric layer 167, e.g., Hafnium oxide, having a thickness, T₂, and a metal or oxide layer 166, e.g., Titanium nitride, Lanthanum oxide, Aluminum oxide, etc., having a thickness, T₃.

FIG. 11B is a simplified diagram illustrative of an optical modulation target 170 employed as part of a multiple pass measurement, along with primary target 165 depicted in FIG. 11A. As depicted in FIG. 11B, optical modulation target 170 is similar to primary target 165, except the thickness of the interface layer, high-K layer, and metal or oxide layer are each three times that of the corresponding layers of primary target 165. As depicted in FIG. 11B, the optical modulation target 170 includes a substrate 174, e.g., Silicon, an interface layer 173, e.g., Silicon dioxide, having a thickness, 3*T₁, a high-K dielectric layer 172, e.g., Hafnium oxide, having a thickness, 3*T₂, and a metal or oxide layer 171, e.g., Titanium nitride, Lanthanum oxide, Aluminum oxide, etc., having a thickness, 3*T₃.

In one embodiment, a two pass SE measurement of primary target 165 that includes an optical pass of optical modulation target 170 is simulated where the thickness of a silicon dioxide interface layer 169 is 10 Angstroms, the thickness of a hafnium oxide High-K layer 167 is 18 Angstroms and the thickness of a titanium nitride metal layer 166 is 10 Angstroms. Similarly, the thickness of a silicon dioxide interface layer 173 is 30 Angstroms, the thickness of a hafnium oxide High-K layer 172 is 54 Angstroms and the thickness of a Titanium nitride metal layer 171 is 30 Angstroms.

In a further aspect, metrology systems 100 and 200 also include computing system 130 configured to implement an electrical performance prediction engine employed to predict values of one or more electrical performance metrics based on structural measurements as described herein.

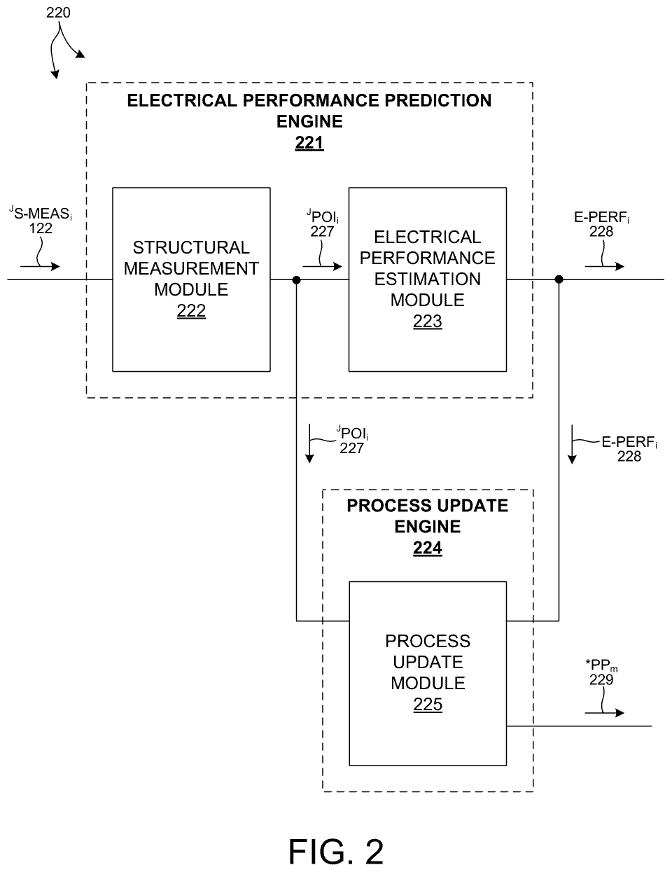

FIG. 2 is a diagram illustrative of an electrical performance prediction engine 221 in one embodiment. As depicted in FIG. 2, electrical performance prediction engine 221 includes a structural measurement module 222 and an electrical performance estimation module 223. As depicted in FIG. 2, measurement signals, ^{J}S-MEASᵢ 122, are received by structural measurement module 222. Superscript J is indicative of a set of positive integer numbers ranging from 1 to J corresponding to measurement signals associated with measurements at each of J different process steps. In general, J can be any positive integer number. In some embodiments, measurements are performed at only one step, i.e., J=1. However, in general, measurements may be performed at J different critical process steps. Subscript i is indicative of a set of positive integer numbers ranging from 1 to i corresponding to each different measurement site measured on a wafer. Structural measurement module 222 includes measurement models employed to estimate values of one or more parameters of interest characterizing the structure under measurement at each measurement site and each process step, ^{J}POIᵢ 227. Structural parameters of interest, ^{J}POIᵢ 227, are communicated to electrical performance estimation module 223. Electrical performance estimation module 223 includes a process model employed to predict the values of one or more electrical performance metrics, E-PERFᵢ 228 associated with each measurement site, i.e., each measured device under fabrication, based on the corresponding estimated values of the structural parameters of interest, ^{J}POIᵢ 227. For example, when J equals one, electrical performance estimation module 223 predicts the values of one or more electrical performance metrics, E-PERFᵢ 228 associated with each measurement site based on structural measurements performed at one process step. When J equals two, electrical performance estimation module 223 predicts the values of one or more electrical performance metrics, E-PERFᵢ 228 associated with each measurement site based on structural measurements performed at two process steps.

In another further aspect, metrology systems 100 and 200 also include computing system 130 configured to implement a process update engine employed to determine an updated value of one or more process parameters characterizing one of the process steps before the last step of the set of FEOL process steps. In some examples, an updated value is associated with a process step performed before the measurements are performed. In these examples, the updated values of the one or more process parameters will change the process applied to subsequent wafers to be processed in the process flow. In some examples, the updated value is associated with a process step to be performed after the measurements are performed. In these examples, the updated values of the one or more process steps will change the process to be applied to the measured wafer and subsequent wafers in the process flow.

FIG. 2 illustrates process update engine 224 in one embodiment. As depicted in FIG. 2, process update engine 224 includes a process update module 225. In the embodiment depicted in FIG. 2, structural parameters of interest, ^{J}POIᵢ 227, and the values of one or more electrical performance metrics, E-PERFᵢ 228 are communicated to process update module 225. Process update module 225 includes a process model employed to generate updated values of one or more process parameters, *PPₘ 229, based on the structural parameters of interest, ^{J}POIᵢ 227, and the values of one or more electrical performance metrics, E-PERFᵢ 228. Subscript m is indicative of a set of positive integer numbers ranging from 1 to m corresponding to each different process parameter. In general, m can be any positive integer number. In some other embodiments, process update module 225 includes a process model employed to generate updated values of one or more process parameters, *PPₘ 229, based on the values of one or more electrical performance metrics, E-PERFᵢ 228, only. In these embodiments, structural parameters of interest, ^{J}POIᵢ 227, are not communicated to process update module 225.

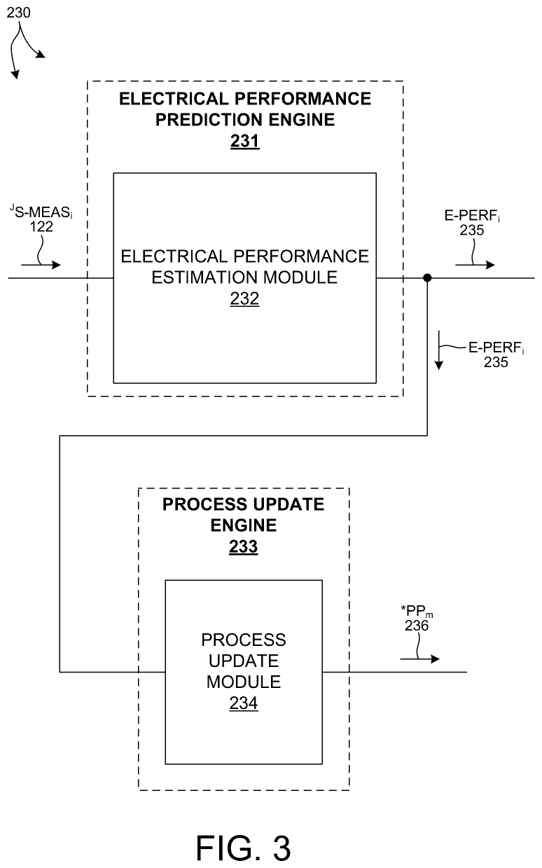

FIG. 3 is a diagram illustrative of an electrical performance prediction engine 231 and a process update engine 233 in another embodiment. As depicted in FIG. 3, electrical performance prediction engine 231 includes an electrical performance estimation module 232. As depicted in FIG. 3, measurement signals, ^{J}S-MEASᵢ 122, are received by electrical performance estimation module 232.

Electrical performance estimation module 232 includes a trained, machine learning based model employed to predict the values of one or more electrical performance metrics, E-PERFᵢ 235 associated with each measurement site, i.e., each measured device under fabrication, based on measurement signals, ^{J}S-MEASᵢ 122.

As depicted in FIG. 3, process update engine 233 includes a process update module 234. In the embodiment depicted in FIG. 3, the values of one or more electrical performance metrics, E-PERFᵢ 235, are communicated to process update module 234. Process update module 234 includes a process model employed to generate updated values of one or more process parameters, *PPₘ 236, based on the values of one or more electrical performance metrics, E-PERFᵢ 235.

In a further aspect, the machine learning based electrical performance prediction model is trained based on measurement signals, ^{J}S-MEASₖ^{DOE}, collected from measurement sites on a set of Design Of Experiments (DOE) wafers, and corresponding values of electrical performance metrics, E-PERFₖ^{DOE}, measured by trusted electrical performance tests performed after FEOL processing steps are completed on the DOE wafers. Subscript k is indicative of a set of positive integer numbers ranging from 1 to k corresponding to each different measurement site measured on the set of DOE wafers. In some examples, the same set of measurement site locations measured on in-line wafers are selected for measurement on the DOE wafers for purposes of model training.

In some examples, training data is generated synthetically, and the synthetically generated training data is employed together with actual DOE training data to train the electrical performance model. In these examples, structural measurement signals and corresponding electrical performance values after FEOL steps are generated by simulation, e.g., simulated from a measurement system simulation model and a process simulation model.

In some examples, training data is generated based on actual measurement signals collected from measurement sites on a set of in-line production wafers, and corresponding values of electrical performance metrics measured by trusted electrical performance tests performed after FEOL processing steps are completed on the in-line, production wafers. In these examples, in-line, production training data is employed to retrain an existing trained electrical performance prediction model based on actual production wafer data. In this manner, the accuracy of a trained electrical performance prediction model may be improved by training on larger data sets generated from actual, production wafers.

In some examples, the machine learning based electrical performance model is a neural network based model. In these examples, the coefficients of the neural network model are trained based on the DOE training datasets.

In general, any parameterized mathematical function may be employed as a trained electrical performance model, e.g., polynomial model, a response surface model, a support vector machines model, a decision tree model, a random forest model, a kernel regression model, a deep network model, a convolutional network model, or other types of models. The coefficients of the parameterized mathematical function are selected to best fit the DOE map of values of electrical performance and corresponding measurement signals.

In some preferred embodiments, electrical performance of in-die devices are predicted in accordance with the methods and systems described herein. In some other embodiments, electrical performance of devices fabricated in scribe lines are predicted in accordance with the methods and systems described herein.

Structural measurements performed by a multiple pass spectroscopic measurement system are described herein. However, in general, expected electrical performance may be calculated based on measurements performed by a multiple pass spectroscopic measurement system and another metrology system, e.g., a spectroscopic reflectometer, an angle-resolved reflectometer, an x-ray photoemission spectroscopy system sensitive to composition, an x-ray fluorescence system sensitive to composition, an x-ray diffractometer sensitive to channel stress and carrier mobility, a raman spectrometer sensitive to channel stress and carrier mobility, etc.

In a further aspect, multiple pass measurements using different combinations of optical modulation targets are combined in a multi-target measurement to further enhance measurement sensitivity and break correlations.

In one example, measurement signals are associated with a two pass measurement of primary target 150 depicted in FIG. 7, a two pass measurement of primary target 150 including optical modulation element 151 having a thickness of 50 nanometers depicted in FIG. 9, and a two pass measurement of primary target 150 including optical modulation element 152 having a thickness of 100 nanometers depicted in FIG. 10. A multi-pass, multi-target measurement model receives the measurement signals and estimates the values of one or more structural parameters of interest based on the received measurement signals. In one example, the parameter of interest is the inner spacer critical dimension (ISCD) of GAA structure 150 depicted in FIG. 7. In another example, the parameter of interest is the metal gate critical dimension (MGCD) of GAA structure 150 depicted in FIG. 7. In another example, the parameter of interest is the sheet thickness (T_{SHEET}) of GAA structure 150 depicted in FIG. 7.

In some examples, the use of a silicon dioxide film on a silicon substrate as an optical modulator as depicted in FIGS. 9 and 10 as part of a multiple pass, multiple target measurement amplifies the measurement sensitivity of an SE measurement of critical parameters of a GAA structure, such as GAA structure 150 depicted in FIG. 7, by 4-10×.

In general, any multi-pass, multi-target measurement model having two or more measurement signal inputs, each associated with a different measurement scenario, is contemplated within this patent document.

In some embodiments, a multi-pass, multi-target measurement model estimates values of one or more parameters of interest based on measurement signals associated with a multiple pass measurement of a primary target without an optical modulation target and measurement signals associated with multiple pass measurements of the primary target with an optical modulation target in any number of configurations.

In some embodiments, a multi-pass, multi-target measurement model estimates values of one or more parameters of interest based on measurement signals associated with multiple pass measurements of a primary target with one or more optical modulation targets in any number of different configurations.

In the embodiment depicted in FIG. 4, computing system 130 is configured to receive signals 122 indicative of the spectral response detected by the detector subsystem. Computing system 130 is further configured to determine control signals 121 that are communicated to programmable illumination source 110. Programmable illumination source 110 receives control signals 121 and adjusts the light output from illumination source 110 to achieve the desired illumination.

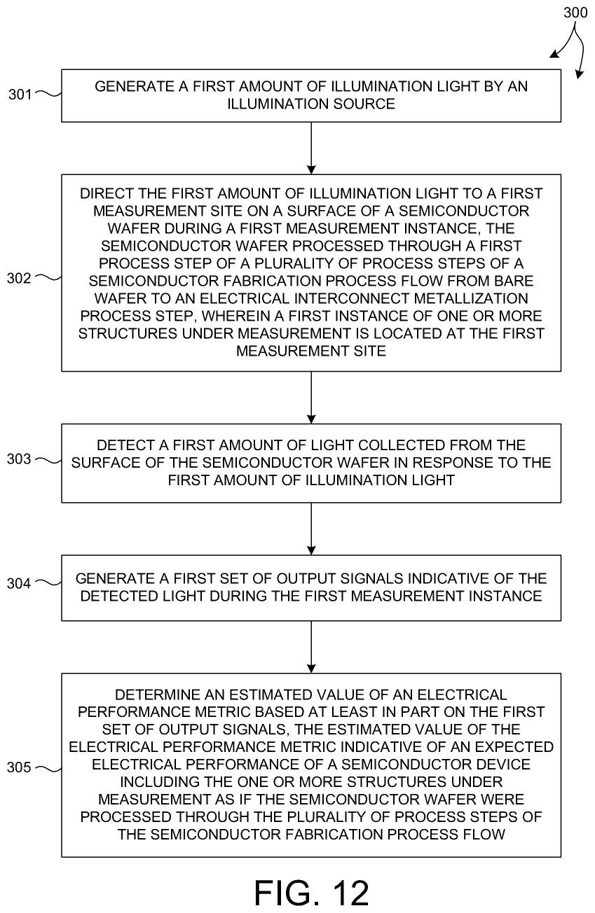

FIG. 12 illustrates a method 300 of estimating electrical performance of unfinished semiconductor devices in at least one novel aspect. Method 300 is suitable for implementation by a metrology system such as metrology systems 100 and 200 illustrated in FIGS. 4 and 6, respectively, of the present invention. In one aspect, it is recognized that data processing blocks of method 300 may be carried out via a pre-programmed algorithm executed by one or more processors of computing system 130, or any other general purpose computing system. It is recognized herein that the particular structural aspects of metrology systems 100 and 200 do not represent limitations and should be interpreted as illustrative only.

In block 301, a first amount of illumination light is generated by an illumination source.

In block 302, the first amount of illumination light is directed to a first measurement site on a surface of a semiconductor wafer during a first measurement instance. The semiconductor wafer is processed through a first process step of a plurality of process steps of a semiconductor fabrication process flow from bare wafer to an electrical interconnect metallization process step. A first instance of one or more structures under measurement is located at the first measurement site.

In block 303, a first amount of light collected from the surface of the semiconductor wafer in response to the first amount of illumination light is detected.

In block 304, a first set of output signals indicative of the detected light during the first measurement instance is generated.

In block 305, an estimated value of an electrical performance metric is determined based at least in part on the first set of output signals. The estimated value of the electrical performance metric is indicative of an expected electrical performance of a semiconductor device including the one or more structures under measurement as if the semiconductor wafer were processed through the plurality of process steps of the semiconductor fabrication process flow.

In a further embodiment, system 100 includes one or more computing systems 130 employed to perform measurements of actual device structures based on spectroscopic measurement data collected in accordance with the methods described herein. The one or more computing systems 130 may be communicatively coupled to the spectrometer. In one aspect, the one or more computing systems 130 are configured to receive measurement data associated with measurements of the structure of the specimen under measurement.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the spectrometers. In another example, the spectrometers may be controlled directly by a single computer system coupled to computer system 130.

The computer system 130 of metrology system 100 may be configured to receive and/or acquire data or information from the subsystems of the system (e.g., spectrometers and the like) by a transmission medium that may include wireline and/or wireless portions. In this manner, the transmission medium may serve as a data link between the computer system 130 and other subsystems of system 100.

Computer system 130 of metrology system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board metrology system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value 171 determined by computer system 130 may be communicated and stored in an external memory. In this regard, measurement results may be exported to another system.

Computing system 130 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

Multiple pass optical measurements of semiconductor structures may be incorporated into many different types of optical measurement systems employed in the semiconductor industry, including, but not limited to: spectroscopic ellipsometers, spectroscopic reflectometers, angle resolved reflectometers, single-wavelength ellipsometers, etc. Measurement signals amplified due to multiple optical passes include, but are not limited to: Mueller matrix signals, harmonic signals, reflectance signals, etc.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO2. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A measurement system comprising:
an illumination source configured to generate a first amount of illumination light directed to a first measurement site on a surface of a semiconductor wafer during a first measurement instance, the semiconductor wafer processed through a first process step of a plurality of process steps of a semiconductor fabrication process flow from bare wafer to an electrical interconnect metallization process step, wherein a first instance of one or more structures under measurement is located at the first measurement site;
at least one detector having a planar, two-dimensional surface sensitive to incident light, the at least one detector configured to detect a first amount of light collected from the surface of the semiconductor wafer in response to the first amount of illumination light and generate a first set of output signals indicative of the detected light during the first measurement instance; and
a computing system configured to determine an estimated value of an electrical performance metric based at least in part on the first set of output signals, the estimated value of the electrical performance metric indicative of an expected electrical performance of a semiconductor device including the one or more structures under measurement as if the semiconductor wafer were processed through the plurality of process steps of the semiconductor fabrication process flow.

2. The measurement system of claim 1, the illumination source further configured to generate a second amount of illumination light directed to the first measurement site on the surface of the semiconductor wafer during a second measurement instance, the semiconductor wafer processed through a second process step of the plurality of process steps, the at least one detector further configured to detect a second amount of light collected from the surface of the semiconductor wafer in response to the second amount of illumination light and generate a second set of output signals indicative of the detected light during the second measurement instance, wherein the determining of the estimated value of the electrical performance metric is based at least in part on the first and second sets of output signals.

3. The measurement system of claim 1, the computing system further configured to:
determine an updated value of one or more process parameters characterizing the first process step, a process step of the plurality of process steps prior to the first process step, a process step subsequent to the first process step of the plurality of process steps, or any combination thereof, based on the estimated value of the electrical performance metric.

4. The measurement system of claim 1, the computing system further configured to:
estimate values of one or more parameters of interest characterizing one or more structural features of the one or more structures under measurement based at least in part on the first set of output signals, wherein the determining of the estimated value of the electrical performance metric is based at least in part on the estimated values of the parameters of interest.

5. The measurement system of claim 4, the computing system further configured to:
determine an updated value of one or more process parameters characterizing the first process step, a process step of the plurality of process steps prior to the first process step, a process step subsequent to the first process step of the plurality of process steps, or any combination thereof, based on the estimated value of the electrical performance metric and the estimated values of the one or more parameters of interest.

6. The measurement system of claim 1, wherein the semiconductor device is a logic device, and wherein the electrical performance metric is any of a drive current, a threshold voltage, a carrier mobility, a current leakage, and a breakdown voltage.

7. The measurement system of claim 1, wherein the semiconductor device is a memory device, and wherein the electrical performance metric is any of a capacitance, a read and write speed, and a reliability.

8. The measurement system of claim 1, wherein the semiconductor device is a gate-all-around transistor.

9. The measurement system of claim 1, wherein the one or more structures under measurement are fabricated in-die.

10. The measurement system of claim 1, wherein the illumination source, the at least one detector, and the computing system comprise a Multiple Pass Spectroscopic Ellipsometry (MPSE) metrology system.

11. The measurement system of claim 10, further comprising:
one or more reflective optical elements disposed in an optical path between the illumination source and the at least one detector, wherein the optical path is incident on the surface of the semiconductor wafer more than once.

12. The measurement system of claim 11, the one or more reflective optical elements including at least two reflective optical elements, the at least two reflective optical elements positioned in the optical path to direct light from the first measurement site back to the first measurement site.

13. The measurement system of claim 11, the one or more reflective optical elements including a planar reflector having a planar reflective surface disposed over the wafer and facing the wafer surface, wherein the planar reflector is positioned in the optical path to direct light from the first measurement site to a second measurement site on the surface of the semiconductor wafer, wherein a second instance of the one or more structures under measurement is located at the second measurement site.

14. The measurement system of claim 10, further comprising:
a second metrology system configured to generate a second set of output signals indicative of a measurement of the one or more structures under measurement, wherein the determining of the estimated value of the electrical performance metric is based on the first and second sets of output signals.

15. The measurement system of claim 14, wherein the second metrology system is a spectroscopic reflectometer, an angle resolved reflectometer, a x-ray diffractometer, or a raman spectrometer.

16. A method comprising:
generating a first amount of illumination light by an illumination source;
directing the first amount of illumination light to a first measurement site on a surface of a semiconductor wafer during a first measurement instance, the semiconductor wafer processed through a first process step of a plurality of process steps of a semiconductor fabrication process flow from bare wafer to an electrical interconnect metallization process step, wherein a first instance of one or more structures under measurement is located at the first measurement site;
detecting a first amount of light collected from the surface of the semiconductor wafer in response to the first amount of illumination light;
generating a first set of output signals indicative of the detected light during the first measurement instance; and
determining an estimated value of an electrical performance metric based at least in part on the first set of output signals, the estimated value of the electrical performance metric indicative of an expected electrical performance of a semiconductor device including the one or more structures under measurement as if the semiconductor wafer were processed through the plurality of process steps of the semiconductor fabrication process flow.

17. The method of claim 16, further comprising:
generating a second amount of illumination light directed to the first measurement site on the surface of the semiconductor wafer during a second measurement instance, the semiconductor wafer processed through a second process step of the plurality of process steps;
detecting a second amount of light collected from the surface of the semiconductor wafer in response to the second amount of illumination light;
generating a second set of output signals indicative of the detected light during the second measurement instance, wherein the determining of the estimated value of the electrical performance metric is based at least in part on the first and second sets of output signals.

18. The method of claim 16, further comprising:
determining an updated value of one or more process parameters characterizing the first process step, a process step of the plurality of process steps prior to the first process step, a process step subsequent to the first process step of the plurality of process steps, or any combination thereof, based on the estimated value of the electrical performance metric.

19. The method of claim 16, further comprising:
estimating values of one or more parameters of interest characterizing one or more structural features of the one or more structures under measurement based at least in part on the first set of output signals, wherein the determining of the estimated value of the electrical performance metric is based at least in part on the estimated values of the parameters of interest.

20. The method of claim 19, further comprising:
determining an updated value of one or more process parameters characterizing the first process step, a process step of the plurality of process steps prior to the first process step, a process step subsequent to the first process step of the plurality of process steps, or any combination thereof, based on the estimated value of the electrical performance metric and the estimated values of the one or more parameters of interest.

21. A measurement system comprising:
an illumination source configured to generate a first amount of illumination light directed to a first measurement site on a surface of a semiconductor wafer during a first measurement instance, the semiconductor wafer processed through a first process step of a plurality of process steps of a semiconductor fabrication process flow from bare wafer to an electrical interconnect metallization process step, wherein a first instance of one or more structures under measurement is located at the first measurement site;
at least one detector having a planar, two-dimensional surface sensitive to incident light, the at least one detector configured to detect a first amount of light collected from the surface of the semiconductor wafer in response to the first amount of illumination light and generate a first set of output signals indicative of the detected light during the first measurement instance; and
a non-transitory, computer-readable medium storing instructions that, when executed by one or more processors, causes the one or more processors to:
determine an estimated value of an electrical performance metric based at least in part on the first set of output signals, the estimated value of the electrical performance metric indicative of an expected electrical performance of a semiconductor device including the one or more structures under measurement as if the semiconductor wafer were processed through the plurality of process steps of the semiconductor fabrication process flow.
